(19) United States
(12) Patent Application Publication
(10) Pub. No.: US 2026/0344405 A1
(43) Pub. Date: Oct. 29, 2026

(54) SEMICONDUCTOR PACKAGE AND METHOD FOR MANUFACTURING THE SAME

(71) Applicant: Samsung Electronics Co., Ltd., Suwon-si (KR)

(72) Inventors: Yusuke TANAKA, Yokohama-shi (JP); Keiichiro HATTORI, Yokohama-shi (JP); Takashi KARIYA, Yokohama-shi (JP); Toshiki FURUTANI, Yokohama-shi (JP)

(73) Assignee: Samsung Electronics Co., Ltd., Suwon-si (KR)

(21) Appl. No.: 19/370,194

(22) Filed: Oct. 27, 2025

(30) Foreign Application Priority Data
Apr. 24, 2025 (JP) 2025-072352
Jun. 17, 2025 (KR) 10-2025-0079546

(51) Int. Cl. H10W 20/43; H10W 20/20; H10W 72/00; H10W 72/20; H10W 72/90; H10W 90/00

(52) U.S. Cl. CPC H10W 20/43; H10W 20/20; H10W 90/00; H10W 72/07253; H10W 72/234; H10W 72/934; H10W 72/942; H10W 90/722

(57) ABSTRACT

A semiconductor package includes a plurality of semiconductor chips. Each semiconductor chip includes a semiconductor substrate having a first main surface and a second main surface, a through-via penetrating through the semiconductor substrate from the first main surface to the second main surface, a first electrode on the through-via on the first main surface, a solder on the first electrode, and a second electrode on the through-via on the second main surface and having a convex shape. The plurality of semiconductor chips includes a first semiconductor chip and a second semiconductor chip below the first semiconductor chip and the first electrode of the first semiconductor chip and the second electrode of the second semiconductor chip are electrically connected to each other via the solder.

### CROSS-REFERENCE TO RELATED APPLICATION(S)

This application claims benefit of priority to Korean Patent Application No. 10-2025-0079546 filed on Jun. 17, 2025 in the Korean Intellectual Property Office and 2025-072352 filed on Apr. 24, 2025 in the Japan Patent Office, the disclosures of which are incorporated herein by reference in their entirety.

### BACKGROUND

A packaging technology of stacking and bonding a plurality of semiconductor chips having a through-via formed by a through-silicon via (TSV) is known. For example, Japanese Patent Publication JP-2024-097288 discloses a semiconductor package having a semiconductor package in which a plurality of semiconductor chips are connected to each other via solder bumps.

### SUMMARY

The inventive concepts relate to a semiconductor package and a method for manufacturing a semiconductor package.

In the semiconductor package having a bonding structure using solder bumps described above, as the number of input/output terminals of an integrated circuit formed in a semiconductor chip increases, it is desirable, to make each, or one or more, solder bump smaller and shorten a distance between adjacent solder bumps (pitch of the bumps). However, when the bump pitch is shorter than 20 μm, the following problems may appear.

By miniaturizing the solder bumps, the amount of solder in each, or one or more, solder bump is reduced. In addition, in general, when bonding semiconductor chips by solder bumps, first, a process (hereinafter also referred to as “a wetback process”) is performed in which the solder formed by interposing a seed layer on an electrode (pad) of the semiconductor chip is heated and melted to form a spherical shape with the solder. By forming the solder bump with the wetback process, the solder bump and the electrode are reliably bonded, while an intermetallic compound (IMC) is formed between the solder bump and the seed layer. Accordingly, the amount of solder in the solder bump is further reduced. Thereafter, the semiconductor chip and another semiconductor chip are bonded by interposing the solder bump therebetween by thermal compression bonding (TCB). Here, if the amount of solder in the solder bump is small, poor connection between the semiconductor chips may occur.

Meanwhile, if TCB is performed without performing the wetback process, since the solder is non-spherical, a non-conductive film (NCF) may not be properly squeezed out between the solder and the electrode of a semiconductor substrate to be bonded and may remain, resulting in poor connection between the semiconductor chips.

Some example embodiments of the inventive concepts provide a semiconductor package having high connectivity between semiconductor chips.

According to some example embodiments of the inventive concepts, a semiconductor package includes a plurality of semiconductor chips, wherein each of the plurality of semiconductor chips includes a semiconductor substrate having a first main surface and a second main surface, opposite to the first main surface, a through-via penetrating through the semiconductor substrate from the first main surface to the second main surface, a first electrode on the through-via on the first main surface, a solder on the first electrode, and a second electrode on the through-via on the second main surface and having a convex shape, wherein the plurality of semiconductor chips includes a first semiconductor chip and a second semiconductor chip below the first semiconductor chip, and the first electrode of the first semiconductor chip and the second electrode of the second semiconductor chip are electrically connected to each other via the solder.

In some example embodiments, the second electrode may be on the second main surface directly above the through-via.

In some example embodiments, the through-via may protrude from the second main surface, and the second electrode may cover a protruding portion of the through-via.

In some example embodiments, each of the plurality of semiconductor chips may further include an insulating layer on the second main surface of the semiconductor substrate, and the insulating layer may protrude toward an axial line of the through-via.

In some example embodiments, the through-via may penetrate through the insulating layer, and a height from the a flat surface reference of the insulating layer to a peak of the through-via on the second main surface may be 0.5 μm or more and 3.0 μm or less.

In some example embodiments, the second electrode may have a tapered shape.

In some example embodiments, a height from a flat portion of the second electrode to a peak of the second electrode may be 0.5 μm or more and 3.0 μm or less.

In some example embodiments, the through-via may include a plurality of through-vias, and a distance between through-vias, of the plurality of through-vias, adjacent to each other in a horizontal direction of the semiconductor substrate may be 10 μm or more and 20 μm or less.

According to some example embodiments of the inventive concepts, a semiconductor package includes a first semiconductor chip including a first semiconductor substrate having a first main surface and a first electrode on the first main surface, a second semiconductor chip including a second semiconductor substrate having a second main surface facing the first main surface in a first direction, a through-via penetrating through the second semiconductor substrate, and a second electrode on the through-via of the second main surface, a solder electrically connecting the first electrode and the second electrode facing each other, and a non-conductive film between the first semiconductor chip and the second semiconductor chip and surrounding the solder, wherein the second electrode includes an inclined portion overlapping the through-via in a second direction, perpendicular to the first direction, and a protrusion portion extending from the inclined portion and covering an upper surface of the through-via.

In some example embodiments, the protrusion portion may not overlap the through-via in the second direction.

In some example embodiments, the upper surface of the through-via may be a convex curved surface in a direction toward the protrusion portion.

In some example embodiments, the inclined portion may have a concave outer surface in a direction toward the through-via.

In some example embodiments, the solder may include a first portion contacting the concave outer surface of the inclined portion and a second portion on the first portion, and a width of the first portion in the second direction may be greater than a width of the second portion in the second direction.

In some example embodiments, the second portion may not overlap the second electrode in the second direction.

In some example embodiments, the through-via may further include a concave surface bent and extending from an edge of the upper surface and contacting the inclined portion.

According to some example embodiments of the inventive concepts, a semiconductor package includes a plurality of semiconductor chips stacked in a first direction, wherein each of the plurality of semiconductor chips includes a semiconductor substrate having a first main surface and a second main surface, opposite to the first main surface, a first insulating layer on the first main surface of the semiconductor substrate, a second insulating layer on the second main surface of the semiconductor substrate, a through-via penetrating through the semiconductor substrate and the second insulating layer, a first electrode on the first insulating layer, and a second electrode on the second insulating layer, and a solder between the first electrode and the second electrode adjacent in the first direction, wherein the first electrode includes a concave portion depressed toward the first main surface and electrically connected to the through-via, and the second electrode includes a convex portion protruding opposite to the second main surface and electrically connected to the through-via.

In some example embodiments, the concave portion of the first electrode and the convex portion of the second electrode may overlap in the first direction.

In some example embodiments, the solder may surround a perimeter of the convex portion.

In some example embodiments the through-via may have an upper surface spaced apart from the second main surface by a first distance in the first direction, the second insulating layer may have an upper surface spaced apart from the second main surface by a second distance in the first direction and an inclined surface extending from the upper surface of the second insulating layer toward an upper surface of the through-via, and the first distance may be greater than the second distance.

In some example embodiments, the inclined surface of the second insulating layer may be concave in a direction toward the through-via.

### BRIEF DESCRIPTION OF DRAWINGS

Some example embodiments, features, and advantages of the inventive concepts will be more clearly understood from the following detailed description, taken in conjunction with the accompanying drawings, in which:

FIG. 1A is a diagram schematically illustrating a cross-sectional structure of a semiconductor package according to some example embodiments;

FIG. 1B is a plan view schematically illustrating a semiconductor package according to some example embodiments;

FIG. 2A is a diagram illustrating an example of a manufacturing process of a semiconductor package according to some example embodiments;

FIG. 2B is a diagram illustrating an example of a manufacturing process of a semiconductor package according to some example embodiments;

FIG. 2C is a diagram illustrating an example of a manufacturing process of a semiconductor package according to some example embodiments;

FIG. 2D is a diagram illustrating an example of a manufacturing process of a semiconductor package according to some example embodiments;

FIG. 2E is a diagram illustrating an example of a manufacturing process of a semiconductor package according to some example embodiments;

FIG. 2F is a diagram illustrating an example of a manufacturing process of a semiconductor package according to some example embodiments;

FIG. 2G is a diagram illustrating an example of a manufacturing process of a semiconductor package according to some example embodiments;

FIG. 2H is a diagram illustrating an example of a manufacturing process of a semiconductor package according to some example embodiments;

FIG. 2I is a diagram illustrating an example of a manufacturing process of a semiconductor package according to some example embodiments;

FIG. 2J is a diagram illustrating an example of a manufacturing process of a semiconductor package according to some example embodiments;

FIG. 3 is a diagram schematically illustrating a cross-sectional structure around a second electrode in a semiconductor package according to some example embodiments;

FIG. 4A is a diagram schematically illustrating a cross-sectional structure of a joint portion between a first electrode and a second electrode in a semiconductor package according to some example embodiments;

FIG. 4B is a diagram schematically illustrating a cross-sectional structure of a joint portion between a first electrode and a second electrode in a semiconductor package as a first comparative example;

FIG. 4C is a diagram schematically illustrating a cross-sectional structure of a joint portion between a first electrode and a second electrode in a semiconductor package as a second comparative example;

FIG. 5A is a diagram illustrating some example of a method for manufacturing a semiconductor package according to some example embodiments;

FIG. 5B is a diagram illustrating some example of a method for manufacturing a semiconductor package according to some example embodiments; and

FIG. 5C is a diagram illustrating some example of a method for manufacturing a semiconductor package according to some example embodiments.

### DETAILED DESCRIPTION

Hereinafter, some example embodiments of the inventive concepts will be described with reference to the accompanying drawings.

It will be understood that when an element is referred to as being “connected” or “coupled” to another element, or “contacting” or in “contact with” another element, it can be directly connected or coupled or directly contacting or directly in contact with the other element or intervening elements may be present. In contrast, when an element is referred to as being “directly connected” or “directly coupled” to another element, or “directly contacting” or “in direct contact with” another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items.

When an element is referred to as being “connected to” or “electrically connected to” another element, the element may be directly connected to the other element, or one or more other intervening elements may be present. For example, an element described as being “connected to” another element may be “electrically connected to” the other element. In contrast, when an element is referred to as being “directly connected to” another element there are no intervening elements present.

First, an overview of some example embodiments of the inventive concepts will be described. Meanwhile, in the description below, reference numerals corresponding to components of the disclosure are described in parentheses as examples. A semiconductor package 1 according to some example embodiments of the inventive concepts has a plurality of semiconductor chips 2, each of the plurality of semiconductor chips 2 includes a semiconductor substrate 20 having a first main surface 20a and a second main surface 20b opposite to the first main surface, a through-via 23 formed to penetrate through the semiconductor substrate 20 from the first main surface 20a to the second main surface 20b, a first electrode 21 formed on the through-via 23 of the first main surface 20a, a solder 24 formed on the first electrode, and/or a second electrode 22 formed on the through-via 23 of the second main surface 20b. The plurality of semiconductor chips includes a first semiconductor chip 2_1 and/or a second semiconductor chip 2_2. The second electrode 22 is formed to have a convex shape, and the first electrode 21 of the first semiconductor chip 2_1 and the second electrode 22 of the second semiconductor chip 2_2 are bonded to each other by the solder 24 interposed therebetween.

In the semiconductor package 1, the second electrode 22 may be formed on the through-via 23 adjacent to the second main surface 20b.

In the semiconductor package 1, the through-via 23 may be formed to protrude from the second main surface 20b, and the second electrode 22 may be formed to cover a protruding portion of the through-via 23.

In the semiconductor package 1, the semiconductor chip 2 may additionally include an insulating layer 27 formed on the second main surface 20b of the semiconductor chip 1, and the insulating layer 27 may be formed to protrude toward an axial line P of the through-via 23.

In the semiconductor package 1 above, the second electrode 22 may be formed to have a tapered shape.

In the semiconductor package 1, a height He from a flat portion of the second electrode 22 to the peak of the second electrode 22 may be 0.5 μm or more and 3.0 μm or less.

In the semiconductor package 1, the through-via 23 may penetrate through the insulating layer 27, and based on the flat surface of the insulating layer 27 as a reference, a height Ht from the reference to the peak of the through-via 23 adjacent to the second surface may be 0.5 μm or more and 3.0 μm or less.

In the semiconductor package 1, the through-via 23 may be formed in plural, and a distance between the through-vias adjacent in a plane direction of the semiconductor chip may be 10 μm or more and 20 μm or less.

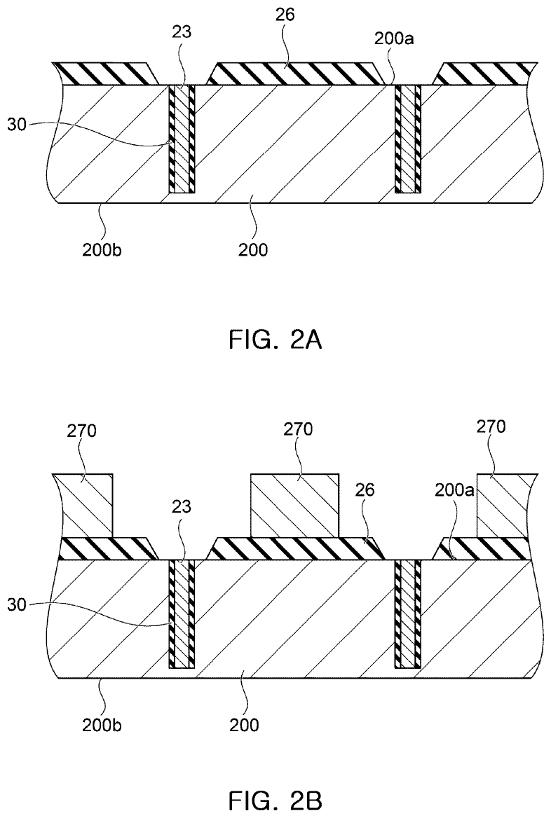

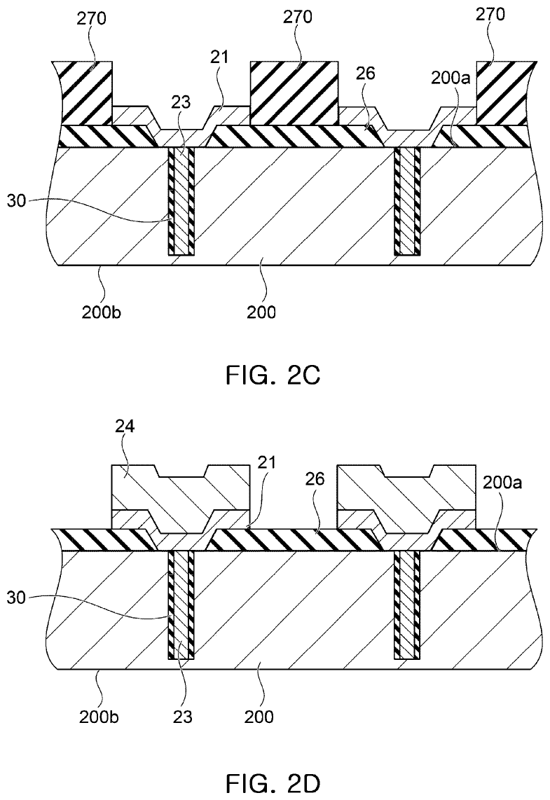

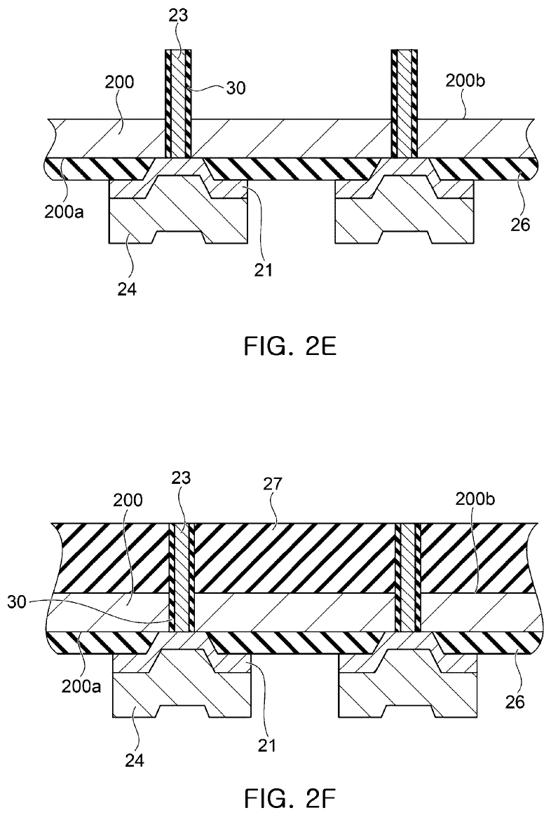

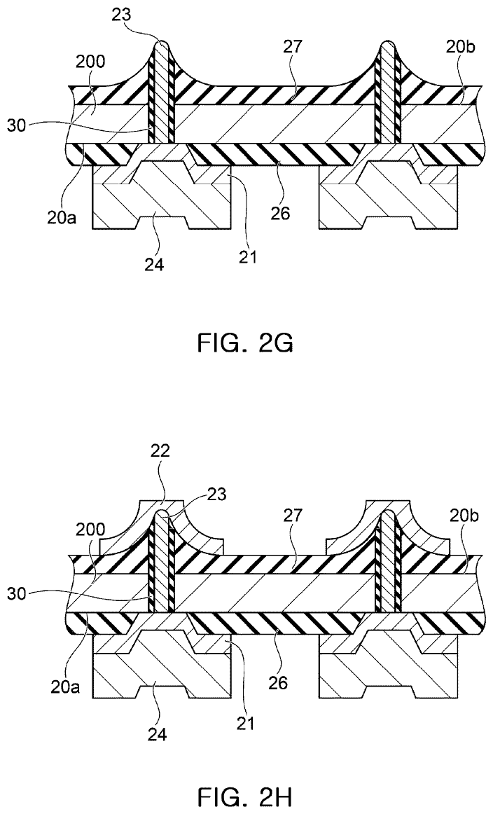

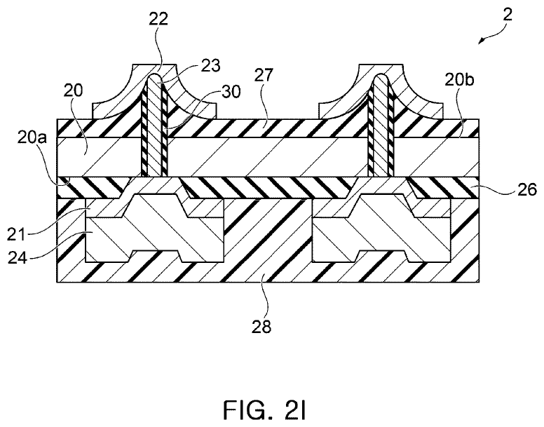

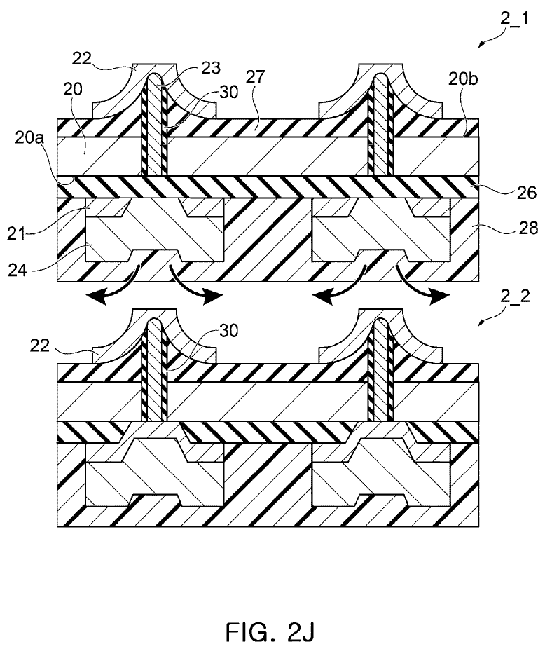

A method for manufacturing the semiconductor package 1 according to some example embodiments includes: a first operation (FIG. 2A) of forming the through-via 23 extending between the first main surface 20a and the second main surface 20b on a semiconductor wafer 200 having the first main surface 20a and the second main surface 20b opposite to the first main surface by using TSV technology; a second operation (FIGS. 2B and 2C) of forming the first electrode 21 on the through-via 23 of the first main surface 20a; a third operation (FIGS. 2C and 2D) of forming the solder 24 on the first electrode 21; a fourth operation (FIGS. 2E, 2F, 2G, and 2H) of forming the second electrode 22 on the through-via 23 of the second main surface 20b and protruding from the second main surface 20b; a fifth operation (FIG. 2I) of dividing the semiconductor wafer 200 into a plurality of semiconductor wafers 200 after the first to fourth operations to prepare a plurality of semiconductor chips 2 including the semiconductor substrate 20, the through-via 23, the first electrode 21, the second electrode 22, and/or the solder 24, and a sixth operation of bonding a first semiconductor chip 2_1 and a second semiconductor chip 2_2 among the plurality of semiconductor chips. The sixth operation includes bonding the first electrode 21 of the first semiconductor chip 2_1 and the second electrode 22 of the second semiconductor chip 2_2 by melting the solder 24 by thermal compression (FIG. 2J).

In the method for manufacturing the semiconductor package, the fourth operation may include a seventh operation (FIGS. 2E, 2F, and 2G) of etching the second main surface 20b side such that the through-via 23 protrudes from the second main surface 20b and an eighth operation (FIG. 2H) of forming the second electrode 22 to cover a protruding portion of the through-via 23.

In the method for manufacturing the semiconductor package, the seventh operation may include a ninth operation (FIG. 2F) of forming the insulating layer 27 on the second main surface 20b and a tenth operation (FIG. 2G) of etching away the insulating layer 27 and the through-via 23 on the second main surface side. In the tenth operation, an etching rate of the insulating layer may be faster than an etching rate of the through-via.

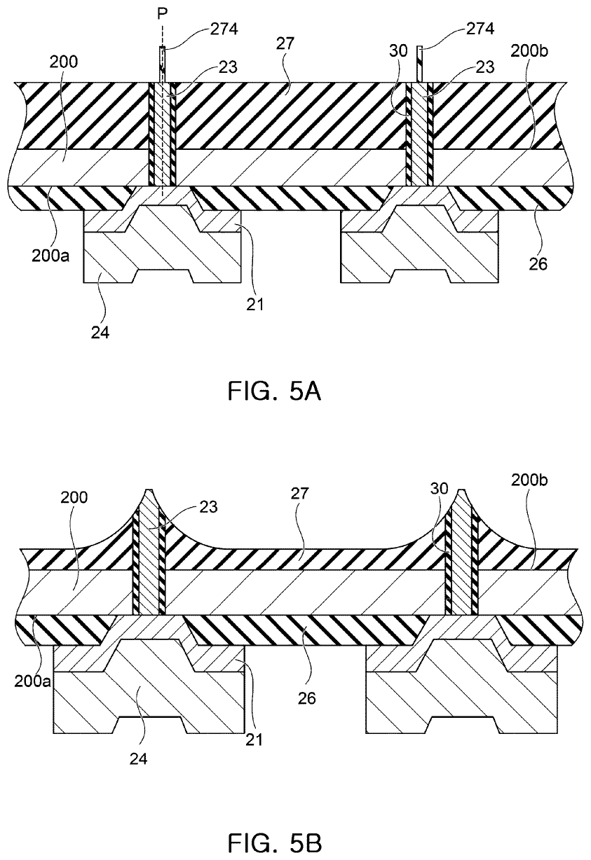

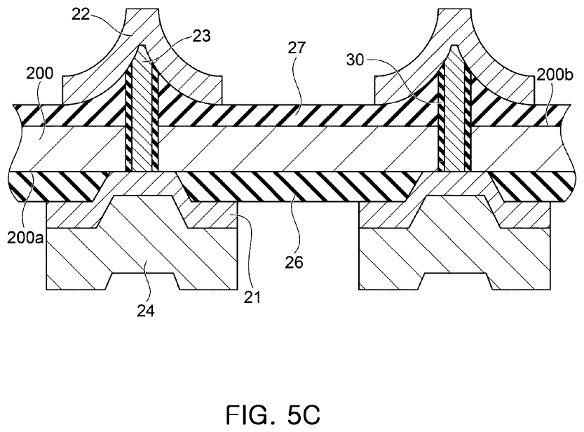

In the manufacturing method of the semiconductor package, the tenth operation may include an eleventh operation (FIG. 5A) of forming a resist pattern 274 covering a portion of the through-via 23 on the axial line P and a twelfth operation (FIG. 5B) of etching away the insulating layer 27 and the through-via 23 after the tenth operation.

Hereinafter, specific examples of some example embodiments of the inventive concepts will be described with reference to the drawings. In the following description, common components are given the same reference numerals, and repeated descriptions are omitted. In addition, the drawings are schematic. That is, in the drawings, the dimensions of each element and the ratio between each element may differ from actual values. In addition, between drawings, the dimensions of each element and the ratio between each element may differ.

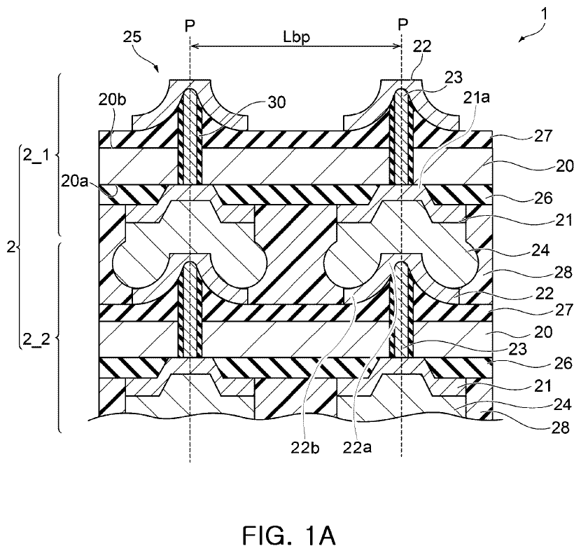

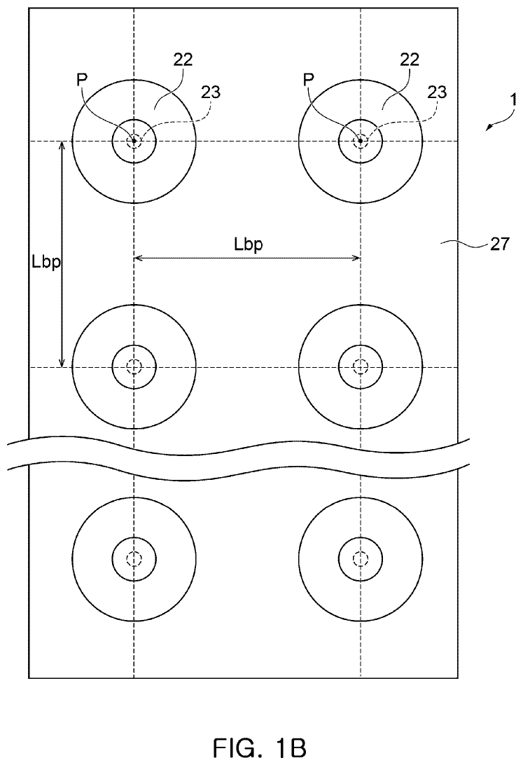

FIG. 1A is a diagram schematically illustrating a cross-sectional structure of the semiconductor package 1 according to some example embodiments.

FIG. 1B is a plan view schematically illustrating the semiconductor package 1 according to some example embodiments.

As illustrated in FIG. 1A, the semiconductor package 1 includes a plurality of stacked semiconductor chips 2 (e.g., 2_1 to 2_n) (n is an integer of 2 or greater). Specifically, the semiconductor package 1 has a bonding structure in which the semiconductor chips 2 having the through-vias 23 formed by, for example, TSV technology are bonded to each other with the solder 24 interposed therebetween.

As an example, a case in which the semiconductor package 1 has two stacked first semiconductor chips 2_1 and second semiconductor chips 2_2 is described, but the number of stacked semiconductor chips in the semiconductor package 1 is not limited. In the following description, the first semiconductor chip is expressed as a “semiconductor chip 2_1”, and the second semiconductor chip is expressed as a “semiconductor chip 2_2.” In addition, when the semiconductor chips 2_1 and 2_2 are not distinguished from each other, there are cases in which each of the plurality of semiconductor chips 2 is expressed as a “semiconductor chip 2.”

The semiconductor chip 2 is, for example, a processor, a memory, a logic integrated circuit (IC), and/or an analog IC. The semiconductor chip 2 includes the semiconductor substrate 20 and/or the first electrode 21, the second electrode 22, the through-via 23, and/or the solder 24 formed on the semiconductor substrate 20.

The semiconductor chip 2 includes a plurality of joint portions 25 each including a set of the first electrode 21, the second electrode 22, the through-via 23, and/or the solder 24. As illustrated in FIGS. 1A and 1B, in the semiconductor chip 2, a distance Lbp between adjacent joint portions 25, e.g., a bump pitch, is, for example, 10 μm or more and 20 μm or less. Here, the distance Lbp between adjacent joint portions 25 refers to a distance between the axial line P of the through-via 23 and the axial line P of another through-via 23 adjacent to the through-via 23.

The semiconductor wafer 200 illustrated in FIG. 2A, etc., is a substrate on which an electronic circuit is formed in each predetermined, or alternately given, region of a wafer by a known semiconductor integrated circuit manufacturing technology. The semiconductor substrate 20 is a chip (die) obtained by dividing the semiconductor wafer 200 into each predetermined, or alternately given, region. In some example embodiments, the wafer is a silicon (Si) substrate. Meanwhile, the wafer is not limited to the silicon substrate and may be a compound semiconductor substrate, such as a gallium nitride (GaN) substrate and/or a silicon carbide (SiC) substrate, and the type of the substrate is not limited.

The semiconductor substrate 20 includes the first main surface 20a and/or the second main surface 20b. The first main surface 20a is, for example, a surface (front side) on which an electronic circuit is formed. The second main surface 20b is a surface (back side) opposite to the first main surface 20a. An insulating layer 26 may be formed on the first main surface 20a of the semiconductor substrate 20, and the insulating layer 27 may be formed on the second main surface 20b of the semiconductor substrate 20.

Meanwhile, in the following description, the surface (front side) on which the electronic circuit is formed in the semiconductor wafer 200 before the semiconductor substrate 20 is divided is referred to as the “first main surface 200a”, and the surface (back side) on the opposite side of the first main surface 200a in the semiconductor wafer 200 is referred to as the “second main surface 200b” (see FIGS. 2A to 2H and FIGS. 5A to 5C).

The through-via 23 is formed to penetrate through the semiconductor substrate 20 from the first main surface 20a to the second main surface 20b of the semiconductor substrate 20. For example, in a direction (stacking direction), perpendicular to the first main surface 20a and the second main surface 20b, the through-via 23 penetrates through the semiconductor substrate 20 and/or the insulating layers 26 and/or 27. The through-via 23 is, for example, a TSV formed by a known TSV technology. An outer peripheral surface of the through-via 23 is in contact with the semiconductor substrate 20 via an insulating layer 30. The through-via 23 is formed to protrude from the second main surface 20b of the semiconductor substrate 20. For example, as illustrated in FIG. 1A, a tip portion on one side of the through-via 23 protrudes from the second main surface 20b of the semiconductor substrate 20 and the insulating layer 27.

The first electrode 21 and/or the second electrode 22 are terminals (pads) for electrically connecting the semiconductor chips 2 to be stacked. The first electrode 21 and/or the second electrode 22 are connected to an electronic circuit formed on the semiconductor substrate 20.

The first electrode 21 is formed on the through-via 23 on the first main surface 20a of the semiconductor substrate 20. For example, the first electrode 21 is formed on the first main surface 20a of the semiconductor substrate 20 so as to overlap the through-via 23 when viewed in the stacking direction of the semiconductor chips 2 (the direction of the axial line P of the through-via 23). The first electrode 21 is in contact with the tip portion of the through-via 23 adjacent to the first main surface 20a.

The second electrode 22 is formed on the through-via 23 adjacent to the second main surface 20b of the semiconductor substrate 20. For example, the second electrode 22 is formed on the second main surface 20b of the semiconductor substrate 20 so as to overlap the through-via 23 when viewed in the stacking direction of the semiconductor chip 2 (the direction of the axial line P of the through-via 23). The second electrode 22 is in contact with the tip portion of the through-via 23 on the second main surface 20b side.

The second electrode 22 is formed to have a convex shape. For example, the second electrode 22 is formed in a shape (taper shape) that becomes thinner away from the first main surface 20a in a direction, perpendicular to the first main surface 20a of the semiconductor substrate 20. For example, the second electrode 22 is formed in a cone shape. Here, the cone shape includes not only a cone with an acute apex, but also a shape, such as a truncated cone (truncated cone or truncated pyramid), with a flat apex as illustrated in FIGS. 1A and 1B.

The insulating layer 27 is formed to protrude toward the axial line P of the through-via 23. In other words, based on the second main surface 20b as a reference, a height from the reference to the insulating layer 27 decreases away from the through-via 23. For example, the insulating layer 27 is formed in a convex shape centered on the axial line P of the through-via 23. The through-via 23 penetrates through the central portion of the convex shape of the insulating layer 27.

As illustrated in FIG. 1A, the second electrode 22 is formed on the through-via 23 of the second main surface 20b and protrudes from the second main surface 20b. For example, the second electrode 22 is formed to cover the portion of the through-via 23 protruding from the second main surface 20b.

The solder 24 includes a metal material for electrically connecting semiconductor chips 2 to each other or a substrate, such as an interposer and/or a printed circuit board, to the semiconductor chip 2. The metal material includes tin (Sn) as a main component. The solder 24 is, for example, a lead-free solder, such as a Sn—Ag system or a Sn—Ag—Cu system.

As illustrated in FIG. 1A, the solder 24 is formed on the first electrode 21. In the semiconductor package 1, the first electrode 21 of one semiconductor chip (the first semiconductor chip) 2_1 and the second electrode 22 of another semiconductor chip (the second semiconductor chip) 2_2 are bonded to each other via the solder 24.

As illustrated in FIG. 1A, the semiconductor package 1 of some example embodiments includes: the first semiconductor chip 2_1 including a first semiconductor substrate 20 having the first main surface 20a and/or the first electrode 21 disposed on the first main surface 20a; the second semiconductor chip 2_2 including a second semiconductor substrate 20 having the second main surface 20b facing the first main surface 20a in a first direction (a vertical direction), the through-via 23 penetrating through the second semiconductor substrate 20, and/or the second electrode 22 disposed on the through-via of the second main surface 20b; the solder 24 connecting the first electrode 21 and the second electrode 22 facing each other; and/or a non-conductive film 28 disposed between the first semiconductor chip 2-1 and the second semiconductor chip 2-2 and surrounding the solder 24. The second electrode 22 may include an inclined portion 22b overlapping the through-via 23 in a second direction (a horizontal direction), perpendicular to the first direction, and/or a protrusion (e.g., a convex portion) 22a extending from the inclined portion 22b and covering an upper surface of the through-via 23.

In some example embodiments, the protrusion 22a may not overlap the through-via 23 in the second direction. The upper surface of the through-via 23 may be a convex curved surface in a direction toward the protrusion 22a. The inclined portion 22b may have a concave outer surface in a direction toward the through-via 23. The solder 24 includes a first portion contacting the outer surface of the inclined portion 22b, and/or a second portion on the first portion. A width of the first portion in the second direction may be greater than a width of the second portion in the second direction. The second portion may not overlap the second electrode 22 in the second direction. The through-via 23 may further include a concave surface bent and extending from the edge of the upper surface contacting the protrusion 22a and contacting the inclined portion 22b.

The semiconductor package 1 of some example embodiments includes a plurality of semiconductor chips 2 stacked in the first direction, each, or one or more, of the plurality of semiconductor chips 2 including the semiconductor substrate 20 having the first main surface 20a and the second main surface 20b opposite to the first main surface 20a, the first insulating layer 26 disposed on the first main surface 20a of the semiconductor substrate 20, the second insulating layer 27 disposed on the second main surface 20b of the semiconductor substrate 20, the through-via 23 penetrating through the semiconductor substrate 20 and/or the second insulating layer 27, the first electrode 21 disposed on the first insulating layer 26, and/or the second electrode 22 disposed on the second insulating layer 27; and/or the solder 24 disposed between the first electrode 21 and the second electrode 22 adjacent in the first direction. The first electrode 21 includes a concave portion 21a depressed toward the first main surface 20a and connected to the through-via 23. The second electrode 22 may include a convex portion 22a protruding opposite to the second main surface 20b and connected to the through-via 23.

In some example embodiments, the concave portion 21a of the first electrode 21 and the convex portion 22a of the second electrode 22 may overlap in the first direction. The solder 24 may surround the perimeter of the convex portion 22a. The through-via 23 may have an upper surface spaced apart from the second main surface 20b by a first distance in the first direction, and the second insulating layer 27 may have an upper surface spaced apart from the second main surface 20b by a second distance in the first direction and an inclined surface extending from the upper surface of the second insulating layer 27 toward the upper surface of the through-via 23. The inclined surface of the second insulating layer 27 may be concave in a direction toward the through-via 23.

Next, a method for manufacturing the semiconductor package 1 according to some example embodiments will be described.

FIGS. 2A to 2F are diagrams illustrating examples of a manufacturing process of the semiconductor package 1 according to some example embodiments.

In each cross-sectional view illustrated below, the illustration of various seed layers is omitted.

First, the semiconductor wafer 200 is prepared in which an electronic circuit is formed in each predetermined, or alternately given, region of the wafer (e.g., a silicon substrate) by a known semiconductor integrated circuit manufacturing technology. Next, as illustrated in FIG. 2A, the through-via 23 is formed in the semiconductor wafer 200. For example, after the insulating layer 26 (e.g., a silicon oxide film (SiO₂)) is formed on the first main surface 200a of the semiconductor wafer 200, the insulating layer 26 in a region for forming the through-via 23 is selectively reduced, or removed. Next, a hole is formed from the first main surface 200a toward the second main surface 200b in the region of the semiconductor wafer 200 in which the insulating layer 26 is selectively reduced, or removed, by a known TSV technology. After the insulating layer 30 is formed on an inner circumferential surface of the hole in the semiconductor wafer 200, the hole is filled with a metal material. The metal material includes, for example, copper (Cu), tungsten (W), and/or aluminum (Al). Accordingly, a TSV is formed as the through-via 23. Here, it is preferable that a diameter Φ of the TSV is 2.5 μm or less.

Next, the first electrode 21 is formed on the through-via 23 on the first main surface 200a side of the semiconductor wafer 200. For example, as illustrated in FIG. 2B, after a seed layer (not illustrated) is formed over the entire surface of the first main surface 200a side of the semiconductor wafer 200, a resist pattern 270 is formed in a region other than a region for forming the first electrode 21 and/or solder 24 by a known photolithography technology. The metal material for the seed layer includes, for example, nickel (Ni). Next, a metal material is deposited in a region not masked by the resist pattern 270 by, for example, a known plating technology (for example, electroplating). The metal material includes, for example, nickel (Ni) and/or gold (Au). Accordingly, as illustrated in FIG. 2C, the first electrode 21 is formed on the through-via 23 of the first main surface 200a.

Next, the solder 24 is formed on the first electrode 21. For example, using the resist pattern 270 used in FIG. 2C as a mask, a metal material (e.g., Sn—Ag type solder) is deposited in a region not masked by the resist pattern 270 by, for example, a known plating technology (e.g., electroplating). Thereafter, as the resist pattern 270 is reduced, or removed, the seed layer on the insulating layer 26 of the semiconductor wafer 200 is also reduced, or removed. Accordingly, as illustrated in FIG. 2D, the solder 24 is formed on the first electrode 21. According to some example embodiments, the wetback process is not performed after the formation of the solder 24.

Next, the second electrode 22 is formed on the through-via 23 of the second main surface 200b of the semiconductor wafer 200 so as to protrude from the second main surface 200b. For example, as illustrated in FIG. 2E, the second main surface 200b side of the semiconductor wafer 200 is set as a surface to be processed, and a portion of the second main surface 200b side of the semiconductor wafer 200 is cut off by a known grinding process and/or reactive ion etching (RIE), and a portion of the through-via 23 protrudes from the semiconductor wafer 200.

Next, as illustrated in FIG. 2F, the insulating layer 27 is formed on the second main surface 200b of the semiconductor wafer 200 by, for example, a known chemical vapor deposition (CVD) method. Thereafter, the second main surface 200b side of the semiconductor wafer 200 is flattened by chemical mechanical polishing (CMP). According to some example embodiments, the insulating layer 27 is, for example, an oxide-nitride-oxide (ONO) layer. According to some example embodiments, a thickness of the insulating layer 27 is preferably 3 μm or less.

Next, on the second main surface 200b side, the insulating layer 27 and the through-via 23 are cut off by, for example, dry etching. For example, the insulating layer 27 may be etched to a thickness of 1.0 μm or less. Here, an etching rate of the insulating layer 27 is faster than an etching rate of the through-via 23. Accordingly, as illustrated in FIG. 2G, the tip portion of the through-via 23 protrudes from the surrounding insulating layer 27. For example, the through-via 23 is in a state of penetrating through the insulating layer 27 formed on the second main surface 200b. Since the edge portion of the through-via 23 is cut off, the tip portion of the through-via 23 becomes hemispherical.

Next, similarly to FIG. 2B, after forming a seed layer (not illustrated) on the entire surface of the second main surface 200b side of the semiconductor wafer 200, a resist pattern (not illustrated) is formed in a region other than the region for forming the second electrode 22. Thereafter, as illustrated in FIG. 2H, a metal material is deposited in a region not masked by the resist pattern by a known plating technology (e.g., electroplating). The metal material includes, for example, nickel (Ni) and/or gold (Au). Accordingly, the second electrode 22 having a convex shape (e.g., a cone shape) is formed on the through-via 23 of the second main surface 200b.

Next, a non-conductive material (e.g., non-conductive film (NCF)) 28 is applied to the entire surface of the first main surface 200a of the semiconductor wafer 200, and then dicing is performed, thereby dividing the semiconductor wafer 200 into a plurality of semiconductor substrates 20. Accordingly, as illustrated in FIG. 2I, a plurality of semiconductor chips 2 including the semiconductor substrate 20, the through-via 23, the first electrode 21, the second electrode 22, and/or the solder 24 are obtained.

Next, the plurality of semiconductor chips 2 are bonded. For example, as illustrated in FIG. 2J, by melting the solder 24 by a known thermocompression bonding technology, such as TCB, the first electrode 21 of one semiconductor chip (the first semiconductor chip) 2_1 and the second electrode 22 of another semiconductor chip (the second semiconductor chip) 2_2 are bonded. A non-conductive material 28 is effectively squeezed out between the solder 24 of the first semiconductor chip 2_1 and the second electrode of the second semiconductor chip 2_2. Accordingly, the semiconductor package 1 illustrated in FIGS. 1A and 1B may be manufactured. Thereafter, by melting the solder 24 of the lowest semiconductor chip (e.g., 2_2) constituting the semiconductor package 1, for example, by a known thermocompression bonding technology, such as TCB, the semiconductor chip 2_2 is bonded to a substrate, such as an interposer and/or a printed circuit board. Accordingly, the semiconductor package 1 is mounted on the substrate.

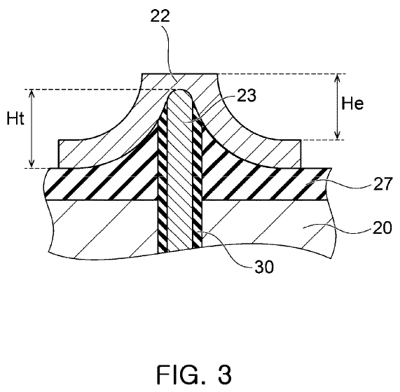

FIG. 3 is a diagram schematically illustrating a cross-sectional structure around the second electrode 22 in the semiconductor package 1 according to some example embodiments.

In a case in which the thickness of the solder 24 after the TCB is included in the range of 1 μm to 4 μm, as illustrated in FIG. 3, the height He from the flat portion of the second electrode 22 to the peak of the second electrode may be 0.5 μm or more and 3.0 μm or less. When the flat surface of the insulating layer 27 is used as a reference, the height Ht from the reference to the peak of the through-via 23 adjacent to the second main surface 20b may be 0.5 μm or more and 3.0 μm or less.

In the semiconductor package 1 according to some example embodiments, the second electrode 22 of the semiconductor chip 2 is formed in a convex shape. Accordingly, when the semiconductor chips 2 are bonded together by the TCB, a contact state of the solder 24 and the second electrode 22 is point contact, so that the non-conductive material (film) 28 between the solder 24 and the second electrode 22 is appropriately squeezed out, thereby increasing the adhesion between the solder 24 and the second electrode 22. For example, since the wetback process for forming the solder 24 into a spherical shape before bonding the semiconductor chips 2 together is not performed, the amount of the interlayer compound (IMC) formed between the solder 24 and the seed layer on the first electrode 21 may be reduced while maintaining an improved connection.

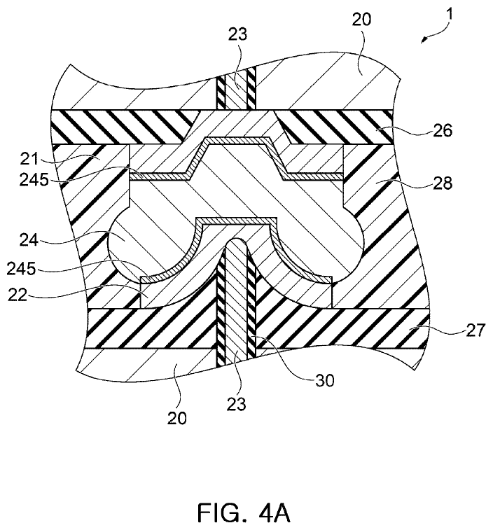

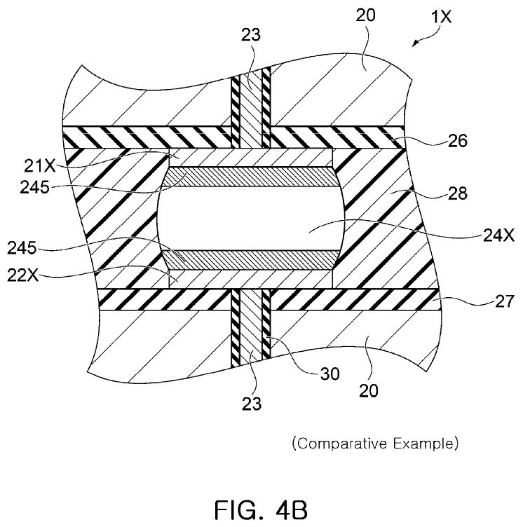

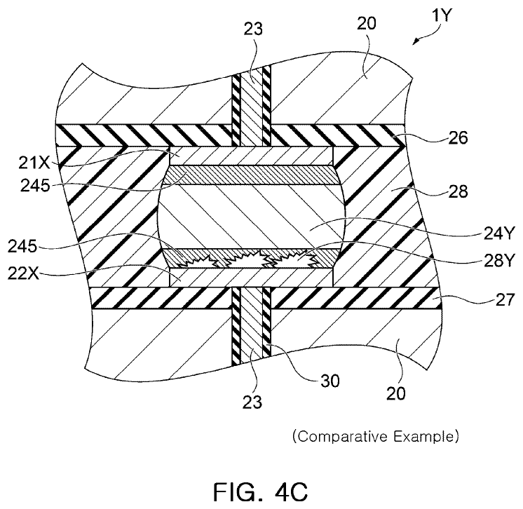

FIG. 4A is a diagram schematically illustrating a cross-sectional structure of a joint portion between the first electrode 21 and the second electrode 22 in the semiconductor package 1 according to some example embodiments. FIG. 4B is a diagram schematically illustrating a cross-sectional structure of a joint portion between a first electrode 21X and a second electrode 22X in a semiconductor package 1X as a first comparative example. FIG. 4C is a diagram schematically illustrating a cross-sectional structure of a joint portion between a first electrode 21X and a second electrode 22X in a semiconductor package 1Y as a second comparative example.

FIG. 4A illustrates a joint portion of the semiconductor package 1 according to Some example embodiments in which two semiconductor chips 2 are bonded by TCB without performing the wetback process. In FIG. 4B, a joint portion of the semiconductor package 1X in which two semiconductor chips are bonded by TCB after the solder is formed to have a spherical shape by the wetback process is illustrated. In FIG. 4C, a joint portion of the semiconductor package 1Y in which two semiconductor chips are bonded by TCB without performing the wetback process is illustrated.

In the case of the semiconductor package 1X illustrated in FIG. 4B, when the second electrode 22X is formed in a flat shape, the wetback process is performed, and then TCB is performed, the layer of an interlayer compound (IMC) 245 formed between the solder 24X and the seed layer on the first electrode 21X and the second electrode 22X becomes thicker. In contrast, as illustrated in FIG. 4A, according to the semiconductor package 1 according to Some example embodiments, since the layer of the interlayer compound 245 formed between the solder 24 and the seed layer on the first electrode 21 and the second electrode 22 may be made thin by not performing the wetback process, it is possible to suppress a decrease in the amount of solder 24.

For example, in the semiconductor package 1Y illustrated in FIG. 4C, when the second electrode 22X is formed in a flat shape and TCB is performed without performing the wetback process, a non-conductive material 28Y remains between the solder 24 and the second electrode 22X, and the adhesion between the solder 24 and the second electrode 22X is reduced. In contrast, as illustrated in FIG. 4A, according to the semiconductor package 1 according to some example embodiments, since the second electrode 22 is in a convex shape, the non-conductive material 28 may be effectively squeezed out between the solder 24 and the second electrode 22 during TCB, thereby increasing the adhesion between the solder 24 and the second electrode 22.

In this manner, according to the method for manufacturing the semiconductor package 1 according to some example embodiments, since the adhesion between the solder 24 and the second electrode 22 may be increased while suppressing the decrease in the amount of solder, the semiconductor package having high connectivity between semiconductor chips 2 may be realized. For example, even in the semiconductor package 1 in which the distance Lbp between adjacent joint portions 25 in the semiconductor chip 2 is 10 μm or more and 20 μm or less due to a large number of input/output terminals, it is possible to secure high connectivity between the semiconductor chips 2.

According to some example embodiments, in the method for manufacturing the semiconductor package 1 according to some example embodiments, the through-via 23 is formed to protrude from the second main surface 20b of the semiconductor substrate 20, and the second electrode 22 is formed to cover the protruding portion of the through-via 23. Accordingly, it is easy to form the second electrode 22 may be found in a convex shape with a reduced manufacturing complexity.

According to some example embodiments, when cutting off the insulating layer 26 and the through-via 23 on the second main surface 20b side by etching, the etching rate of the insulating layer 26 is faster than the etching rate of the through-via 23, so that it is easy to protrude the through-via 23 from the second main surface 20b.

According to some example embodiments, in the sixth operation described above (see FIG. 2J), the through-via 23 may be cut so that the tip portion of the through-via 23 is tapered. Hereinafter, this will be described using FIGS. 5A to 5C.

FIGS. 5A, 5B, and 5C are diagrams illustrating an example of a method for manufacturing the semiconductor package 1 according to some example embodiments.

For example, first, as illustrated in FIG. 5A, the resist pattern 274 covering a portion of the through-via 23 in the axial line P is formed by a known photolithography technology. Next, as illustrated in FIG. 5B, the insulating layer 27 and/or the through-via 23 are cut by a known etching technology. According to this, the tip portion of the through-via 23 becomes tapered. Thereafter, by forming the second electrode 22 by the technique described above, as illustrated in FIG. 5C, the shape of the second electrode 22 may be made closer to a cone. According to this, it is possible to squeeze out the non-conductive material 28 more efficiently during the TCB.

According to some example embodiments of the inventive concepts, a method for manufacturing a semiconductor package includes forming a first semiconductor chip by forming a through-via extending from a first main surface of a substrate to a second main surface of the substrate, the first main surface of the substrate being opposite from the first main surface of the substrate, forming a first electrode on the through-via on the first main surface of the substrate, forming a solder on the first electrode, and forming a second electrode on the through-via and protruding from the second main surface, the second electrode having a convex shape, forming a second semiconductor chip in the same manner as the forming the first semiconductor chip, and bonding the first electrode of the first semiconductor chip to a second electrode of the second semiconductor chip.

In some example embodiments, the bonding the first electrode of the first semiconductor chip to the second electrode of the second semiconductor chip may include melting the solder by thermal compression.

In some example embodiments, the bonding the first electrode of the first semiconductor chip to the second electrode of the second semiconductor chip may not include a wetback process.

In some example embodiments, the forming the first electrode may include forming the first electrode to have a concave shape.

In some example embodiments, the forming the first semiconductor chip may include etching the second main surface such that the through-via protrudes from the second main surface of the substrate.

In some example embodiments, the etching the second main surface may include forming an insulating layer on the second main surface and etching away the insulating layer and the through-via, wherein an etching rate of the insulating layer may be faster than an etching rate of the through-via.

In some example embodiments, the etching away the insulating layer and the through-via may include forming a resist pattern covering a portion of the through-via.

In some example embodiments, the forming the second electrode may include forming the second electrode to cover a protruding portion of the through-via protruding from the second main surface of the substrate.

The inventive concepts have been specifically described based on some example embodiments, but the inventive concepts are not limited thereto and various changes may be made without departing from the gist thereof.

For example, in some example embodiments, the second electrode 22 may be formed to have a convex shape, and a manufacturing process other than the manufacturing process described above may also be used. In addition, the second electrode 22 may have a convex shape and is not limited to the tapered shape described above (for example, a frusto-conical shape).

According to some example embodiments of the inventive concepts, it is possible to realize the semiconductor package having high connectivity between semiconductor chips.

The various advantageous advantages and effects of the inventive concepts are not limited to the above-described contents and will be more easily understood in the course of describing some example embodiments of the inventive concepts.

While some example embodiments have been illustrated and described above, it will be apparent to those skilled in the art that modifications and variations could be made without departing from the scope of the inventive concepts as defined by the appended claims.

What is claimed is:

1. A semiconductor package comprising:
a plurality of semiconductor chips,
wherein each of the plurality of semiconductor chips includes
a semiconductor substrate having a first main surface and a second main surface, opposite to the first main surface,
a through-via penetrating through the semiconductor substrate from the first main surface to the second main surface,
a first electrode on the through-via on the first main surface,
a solder on the first electrode, and
a second electrode on the through-via on the second main surface and having a convex shape,
wherein the plurality of semiconductor chips includes a first semiconductor chip and a second semiconductor chip below the first semiconductor chip, and
wherein the first electrode of the first semiconductor chip and the second electrode of the second semiconductor chip are electrically connected to each other via the solder.

2. The semiconductor package of claim 1, wherein the second electrode is on the second main surface directly above the through-via.

3. The semiconductor package of claim 2, wherein the through-via protrudes from the second main surface, and the second electrode covers a protruding portion of the through-via.

4. The semiconductor package of claim 3, wherein each of the plurality of semiconductor chips further includes an insulating layer on the second main surface of the semiconductor substrate, and the insulating layer protrudes toward an axial line of the through-via.

5. The semiconductor package of claim 4, wherein the through-via penetrates through the insulating layer, and
a height from a flat surface reference of the insulating layer to a peak of the through-via on the second main surface is 0.5 μm or more and 3.0 μm or less.

6. The semiconductor package of claim 3, wherein the second electrode has a tapered shape.

7. The semiconductor package of claim 6, wherein a height from a flat portion of the second electrode to a peak of the second electrode is 0.5 μm or more and 3.0 μm or less.

8. The semiconductor package of claim 1, wherein the through-via includes a plurality of through-vias, and a distance between through-vias, of the plurality of through-vias, adjacent to each other in a horizontal direction of the semiconductor substrate is 10 μm or more and 20 μm or less.

9. A semiconductor package comprising:
a first semiconductor chip including a first semiconductor substrate having a first main surface and a first electrode on the first main surface;
a second semiconductor chip including a second semiconductor substrate having a second main surface facing the first main surface in a first direction, a through-via penetrating through the second semiconductor substrate, and a second electrode on the through-via of the second main surface;
a solder electrically connecting the first electrode and the second electrode facing each other; and
a non-conductive film between the first semiconductor chip and the second semiconductor chip and surrounding the solder,
wherein the second electrode includes an inclined portion overlapping the through-via in a second direction, perpendicular to the first direction, and a protrusion portion extending from the inclined portion and covering an upper surface of the through-via.

10. The semiconductor package of claim 9, wherein the protrusion portion does not overlap the through-via in the second direction.

11. The semiconductor package of claim 9, wherein the upper surface of the through-via is a convex curved surface in a direction toward the protrusion portion.

12. The semiconductor package of claim 9, wherein the inclined portion has a concave outer surface in a direction toward the through-via.

13. The semiconductor package of claim 12, wherein the solder includes a first portion contacting the concave outer surface of the inclined portion and a second portion on the first portion, and
a width of the first portion in the second direction is greater than a width of the second portion in the second direction.

14. The semiconductor package of claim 13, wherein the second portion does not overlap the second electrode in the second direction.

15. The semiconductor package of claim 9, wherein the through-via further includes a concave surface bent and extending from an edge of the upper surface and contacting the inclined portion.

16. A semiconductor package comprising:
a plurality of semiconductor chips stacked in a first direction;
wherein each of the plurality of semiconductor chips includes:
a semiconductor substrate having a first main surface and a second main surface, opposite to the first main surface,
a first insulating layer on the first main surface of the semiconductor substrate,
a second insulating layer on the second main surface of the semiconductor substrate,
a through-via penetrating through the semiconductor substrate and the second insulating layer,
a first electrode on the first insulating layer, and
a second electrode on the second insulating layer; and
a solder between the first electrode and the second electrode adjacent in the first direction,
wherein the first electrode includes a concave portion depressed toward the first main surface and electrically connected to the through-via, and
wherein the second electrode includes a convex portion protruding opposite to the second main surface and electrically connected to the through-via.

17. The semiconductor package of claim 16, wherein the concave portion of the first electrode and the convex portion of the second electrode overlap in the first direction.

18. The semiconductor package of claim 16, wherein the solder surrounds a perimeter of the convex portion.

19. The semiconductor package of claim 16, wherein
the through-via has an upper surface spaced apart from the second main surface by a first distance in the first direction,
the second insulating layer has an upper surface spaced apart from the second main surface by a second distance in the first direction and an inclined surface extending from the upper surface of the second insulating layer toward the upper surface of the through-via, and
the first distance is greater than the second distance.

20. The semiconductor package of claim 19, wherein the inclined surface of the second insulating layer is concave in a direction toward the through-via.
